(19) United States
(12) Patent Application Publication
(10) Pub. No.: US 2026/0180044 A1
(43) Pub. Date: Jun. 25, 2026

(54) ELECTRIFIED VEHICLE

(71) Applicant: Toyota Jidosha Kabushiki Kaisha, Toyota-shi (JP)

(72) Inventor: Soshi OHTA, Okazaki-shi (JP)

(73) Assignee: Toyota Jidosha Kabushiki Kaisha, Toyota-shi (JP)

(21) Appl. No.: 19/355,253

(22) Filed: Oct. 10, 2025

(30) Foreign Application Priority Data
Oct. 23, 2024 (JP) 2024-186758

(51) Int. Cl. H01M 10/42; B60L 58/16; H01M 10/48; H01M 50/249

(52) U.S. Cl. CPC H01M 10/425; B60L 58/16; H01M 10/486; H01M 50/249; B60L 2240/545; B60L 2240/547; B60L 2240/549; H01M 2010/4271; H01M 2220/20

(57) ABSTRACT

An electrified vehicle includes a battery mounted in the electrified vehicle and a control unit. The control unit is configured to acquire battery characteristic information Ei of the battery at predetermined intervals Δt, estimate an internal pressure Pbi of the battery and a cathode potential Vbi of the battery based on the battery characteristic information Ei, increment a cumulative internal pressure value Npi when the internal pressure Pbi exceeds a first threshold Th1, and increment a cumulative potential value Nvi when the cathode potential Vbi exceeds a second threshold Th2. The control unit is configured to calculate a degradation index Exi, and when the degradation index Exi exceeds a third threshold Th3, determine that the battery has degraded. The degradation index Exi is the cumulative internal pressure value Npi multiplied by the cumulative potential value Nvi.

### CROSS-REFERENCE TO RELATED APPLICATION

This application claims priority to Japanese Patent Application No. 2024-186758 filed on Oct. 23, 2024. The disclosure of the above-identified application, including the specification, drawings, and claims, is incorporated by reference herein in its entirety.

### BACKGROUND

### 1. Technical Field

The present disclosure relates to electrified vehicles.

### 2. Description of Related Art

Japanese Unexamined Patent Application Publication No. 2023-12835 (JP 2023-12835 A) discloses a system for estimating the degradation index of each of a plurality of energy storage cells that forms a battery pack mounted in an electrified vehicle. More specifically, an electronic control unit (ECU) of an electrified vehicle acquires the cathode potential of each energy storage cell and the internal pressure of a cell case of each energy storage cell at regular time intervals. The ECU estimates the degradation index of each energy storage cell by accumulating the time during which the acquired cathode potential exceeds a certain threshold and the acquired internal pressure exceeds a certain threshold. The ECU determines that an energy storage cell whose degradation index exceeds a certain threshold is an energy storage cell that has degraded beyond an acceptable level.

### SUMMARY

The degradation index estimation system disclosed in JP 2023-12835 A takes into account only the state in which the acquired cathode potential exceeds a certain threshold and the acquired internal pressure exceeds a certain threshold. In other words, this degradation index estimation system does not take into account, for estimation of the degradation index, a state in which either the acquired cathode potential exceeds a certain threshold or the acquired internal pressure exceeds a certain threshold. As a result, the system disclosed in JP 2023-12835 A cannot detect degradation of energy storage cells at an early stage.

The present disclosure has been made to address the above issue, and an object thereof is to provide an electrified vehicle that can detect, at an early stage, progression of degradation of energy storage cells mounted in the electrified vehicle.

An electrified vehicle according to a first aspect of the present disclosure includes a battery mounted in the electrified vehicle and a control unit. The control unit is configured to acquire battery characteristic information of the battery at predetermined intervals, estimate an internal pressure of the battery and a cathode potential of the battery based on the battery characteristic information, increment a cumulative internal pressure value when the internal pressure exceeds a first threshold, and increment a cumulative potential value when the cathode potential exceeds a second threshold. The control unit is configured to calculate a degradation index, and when the degradation index exceeds a third threshold, determine that the battery has degraded. The degradation index is the cumulative internal pressure value multiplied by the cumulative potential value.

This allows the electrified vehicle to detect degradation of the battery at an earlier stage compared to a degradation detection method in which the degradation index is incremented only when the internal pressure exceeds the first threshold and the cathode potential exceeds the second threshold.

An electrified vehicle according to a second aspect of the present disclosure includes a battery mounted in the electrified vehicle and a control unit. The control unit is configured to acquire, at predetermined intervals, battery characteristic information of the battery in association with a travel distance of the electrified vehicle, estimate an internal pressure of the battery and a cathode potential of the battery based on the battery characteristic information, increment a cumulative internal pressure value when the internal pressure exceeds a first threshold, and increment a cumulative potential value when the cathode potential exceeds a second threshold. The control unit is configured to calculate a degradation index that is the cumulative internal pressure value multiplied by the cumulative potential value. The control unit is configured to calculate a degradation progress based on the degradation index, and when the degradation progress exceeds a fourth threshold, determine that the battery has degraded. The degradation progress is an amount of increase in the degradation index per the travel distance.

With this configuration, degradation of the battery can be detected based on the rate of degradation progression, even when the degradation has not accumulated. That is, the electrified vehicle can detect degradation of the battery at an early stage without waiting for the degradation of the battery to accumulate.

The battery characteristic information may include information on a voltage of the battery, information on a current of the battery, and information on a temperature of the battery.

The battery may be one of energy storage cells that constitute a battery pack. The internal pressure may be a pressure inside a cell case of the energy storage cell. The cathode potential may be a potential at a cathode terminal of the energy storage cell.

The electrified vehicle according to the present disclosure can detect, at an early stage, progression of degradation of energy storage cells mounted in the electrified vehicle.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a schematic configuration diagram of an electrified vehicle according to an embodiment of the present disclosure;

FIG. 2 is a control flowchart of the electrified vehicle according to the embodiment of the present disclosure;

FIG. 3 is a graph showing the relationship between a cumulative internal pressure value and a cumulative potential value according to the embodiment of the present disclosure;

FIG. 4 is a control flowchart of the electrified vehicle according to the embodiment of the present disclosure; and

FIG. 5 is a graph showing the relationship between travel distance and degradation index according to the embodiment of the present disclosure.

### DETAILED DESCRIPTION OF EMBODIMENTS

An embodiment of the present disclosure will be described in detail below with reference to the drawings. The same or corresponding portions are denoted by the same signs throughout the drawings, and description thereof will not be repeated.

### Overall Configuration of Electrified Vehicle

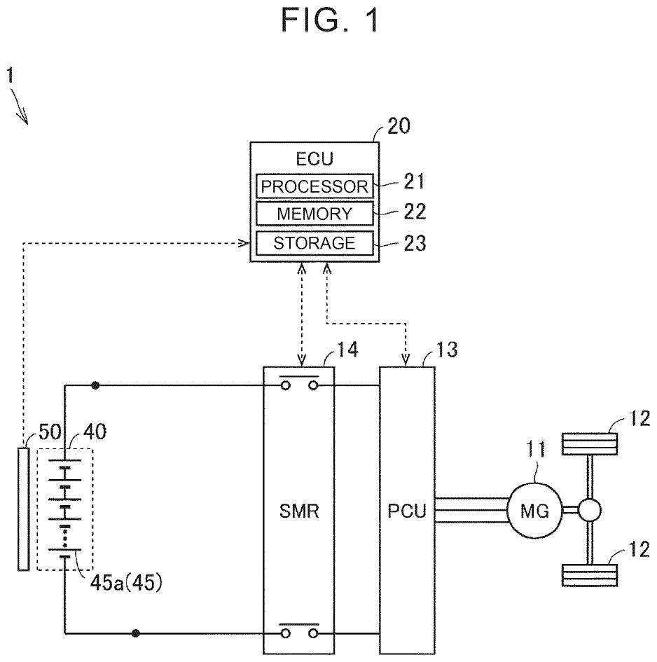

FIG. 1 shows a schematic configuration of an electrified vehicle according to an embodiment of the present disclosure.

An electrified vehicle 1 is, for example, a battery electric vehicle. The electrified vehicle 1 includes a motor generator (MG) 11 that is a rotating electrical machine, drive wheels 12, a power control unit (PCU) 13, a system main relay (SMR) 14, an ECU 20, a battery pack 40, and a monitoring unit 50. The ECU 20 is communicably connected to the PCU 13, the SMR 14, and the monitoring unit 50.

The MG 11 is, for example, an interior permanent magnet synchronous motor (IPM motor) and serves as both an electric motor and a generator. The output torque of the MG 11 is transmitted to the drive wheels 12 via a power transmission device that includes a reduction gear and a differential.

When the electrified vehicle 1 is braking, the MG 11 is driven by the drive wheels 12 and operates as a generator. Accordingly, the MG 11 also serves as a braking device that performs regenerative braking to convert the kinetic energy of the electrified vehicle 1 to electric power. Regenerative power generated by the regenerative braking force of the MG 11 is stored in the battery pack 40.

The PCU 13 is a power conversion device that bidirectionally converts electric power between the MG 11 and the battery pack 40. The PCU 13 includes, for example, an inverter and a converter that operate based on control signals from the ECU 20. During discharge of the battery pack 40, the converter boosts the voltage supplied from the battery pack 40 and supplies the boosted voltage to the inverter. The inverter converts the direct current power supplied from the converter to alternating current power to drive the MG 11. The PCU 13 may be configured without the converter.

The SMR 14 is electrically connected to a power line that connects the battery pack 40 and the PCU 13. When the SMR 14 is closed (ON) in response to a control signal from the ECU 20, electric power can be transferred between the battery pack 40 and the PCU 13. On the other hand, when the SMR 14 is open (OFF) in response to a control signal from the ECU 20, the electrical connection between the battery pack 40 and the PCU 13 is interrupted.

The ECU 20 includes a processor 21, a memory 22, and a storage 23. The processor 21 is a computing device such as a central processing unit (CPU) or a micro-processing unit (MPU). The memory 22 is a volatile memory (working memory) such as a random access memory (RAM). The storage 23 is a rewritable nonvolatile memory such as a flash memory. The storage 23 stores a system program including an operating system (OS) and a control program containing computer-readable code to be used for control computations. The processor 21 implements various processes by reading the system program and the control program, loading them into the memory 22, and executing them. The ECU 20 may be functionally divided into a plurality of ECUs. The ECU 20 is an example of the “control unit” of the present disclosure.

The battery pack 40 is mounted in the electrified vehicle 1 The battery pack 40 includes a plurality of energy storage cells 45. The energy storage cells 45 are electrically connected in series. Each of the energy storage cells 45 is herein referred to as “energy storage cell 45a.” The energy storage cell 45a is a secondary cell such as a nickel metal hydride cell or a lithium-ion cell. The energy storage cell 45a is, for example, a secondary cell having a liquid electrolyte between a cathode and an anode that are enclosed in a cell case. The battery pack 40 is an example of the “battery pack” of the present disclosure. The energy storage cell 45a is an example of the “battery” of the present disclosure.

The monitoring unit 50 includes various sensors that detect the states (for example, temperature, current, and voltage) of the battery pack 40 and each of the energy storage cells 45. The monitoring unit 50 also serves as a battery management system (BMS) having a function to acquire the open circuit voltage (OCV) of each of the energy storage cells 45, an SOC estimation function to estimate the state of charge (SOC) of each of the energy storage cells 45, an SOH estimation function to estimate the state of health (SOH) of each of the energy storage cells 45, and a communication function. The monitoring unit 50 outputs the detection results to the ECU 20.

### Control Flow for Battery Degradation Detection in Electrified Vehicle

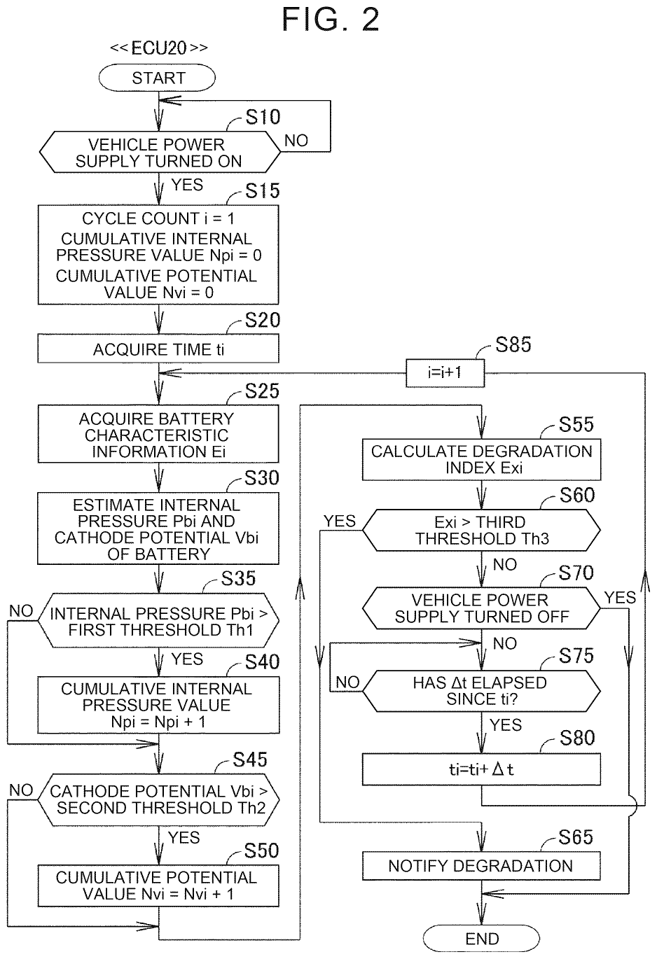

Next, a control flow for battery degradation detection in the electrified vehicle 1 will be described with reference to FIG. 2. In step S10 shown in FIG. 2, the ECU 20 checks whether the vehicle power supply of the electrified vehicle 1 is turned on. The vehicle power supply includes an accessory (ACC) power supply and an ignition (IG) power supply. When the vehicle power supply is turned on, the process of the ECU 20 proceeds to step S15. When the vehicle power supply is not turned on, the ECU 20 performs step S10 again.

In step S15, the ECU 20 sets the initial value of a cycle count i to one and sets the initial values of a cumulative internal pressure value Npi and a cumulative potential value Nvi to zero, and stores the cycle count i, the cumulative internal pressure value Npi, and the cumulative potential value Nvi. The cumulative internal pressure value Npi and the cumulative potential value Nvi are each expressed as zero and a natural number and indicate a count value. The process of the ECU 20 then proceeds to step S20.

In step S20, the ECU 20 stores time ti. The process of the ECU 20 then proceeds to step S25.

In step S25, the ECU 20 acquires battery characteristic information Ei from the monitoring unit 50. The battery characteristic information Ei includes, for example, information on the temperature, current, and voltage of an energy storage cell 45a, namely one of the energy storage cells 45 in the battery pack 40, at time ti. The ECU 20 stores the acquired battery characteristic information Ei. The process of the ECU 20 then proceeds to step S30.

In step S30, the ECU 20 estimates the internal pressure Pbi and the cathode potential Vbi of the energy storage cell 45a at time ti, based on the battery characteristic information Ei. The cathode potential Vbi is the potential at the cathode terminal of the energy storage cell 45a. The internal pressure Pbi indicates the gauge pressure inside the cell case of the energy storage cell 45a. The cathode potential Vbi and the internal pressure Pbi of the energy storage cell 45a are estimated by a known method. For example, JP 2023-12835 A discloses a method for estimating the cathode potential Vbi from the acquired battery characteristic information Ei and known data. The known data is “table data indicating the relationship between the voltage and the anode potential of the energy storage cell 45a.” JP 2023-12835 A also discloses a method for estimating the internal pressure Pbi. More specifically, according to JP 2023-12835 A, the internal pressure reduction rate is calculated based on the acquired battery characteristic information Ei and known data. The known data is “data indicating the relationship between the temperature of the energy storage cell 45a and the gas absorption rate of the anode of the energy storage cell 45a.” The internal pressure reduction rate is corrected based on the battery characteristic information Ei. JP 2023-12835 A discloses a method for estimating the internal pressure Pbi from the corrected internal pressure reduction rate and the internal pressure increase rate calculated based on the battery characteristic information Ei. After the ECU 20 completes the estimation of the internal pressure Pbi and the cathode potential Vbi, the process of the ECU 20 proceeds to step S35.

In step S35, the ECU 20 checks whether the internal pressure Pbi is greater than a first threshold Th1. The first threshold Th1 is, for example, 0.42 MPa·G. When the internal pressure Pbi is greater than the first threshold Th1, the process of the ECU 20 proceeds to step S40. When the internal pressure Pbi is less than or equal to the first threshold Th1, the process of the ECU 20 proceeds to step S45.

In step S40, the ECU 20 increments the cumulative internal pressure value Npi by one. The process of the ECU 20 then proceeds to step S45.

In step S45, the ECU 20 checks whether the cathode potential Vbi is greater than a second threshold Th2. The second threshold Th2 is, for example, 1.0 V. The process of the ECU 20 then proceeds to step S50.

In step S50, the ECU 20 increments the cumulative potential value Nvi by one. The process of the ECU 20 then proceeds to step S55.

In step S55, the ECU 20 calculates a degradation index Exi. The degradation index Exi is calculated using Equation (1).

$$Degradation index Exi = cumulative internal pressure value Npi \times cumulative potential value Nvi \qquad ( 1 )$$

The degradation index Exi (count value) is calculated from the cumulative internal pressure value Npi (count value) and the cumulative potential value Nvi (count value). The process of the ECU 20 then proceeds to step S60.

In step S60, the ECU 20 checks whether the degradation index Exi is greater than a third threshold Th3. The third threshold Th3 is, for example, 1,000,000. When the degradation index Exi of the energy storage cell 45a exceeds the third threshold Th3, the ECU 20 determines that the energy storage cell 45a has degraded.

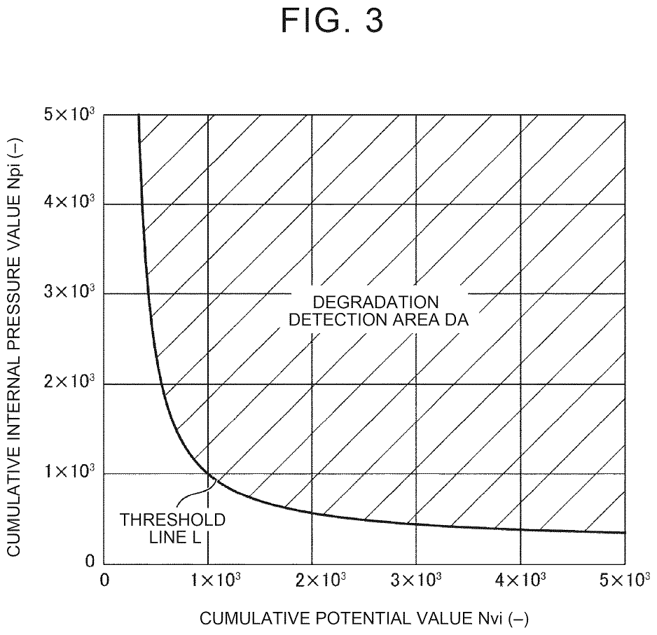

FIG. 3 is a graph showing the relationship between the cumulative potential value Nvi and the cumulative internal pressure value Npi. FIG. 3 shows a threshold line L corresponding to the third threshold Th3 being 1,000,000. FIG. 3 shows a degradation detection area DA defined by the threshold line L. The degradation index Exi is plotted on FIG. 3. When the degradation index Exi is plotted in the degradation detection area DA shown in FIG. 3, that is, when the degradation index Exi is greater than the third threshold Th3, the process of the ECU 20 proceeds to step S65 as shown in FIG. 2. When the degradation index Exi is less than or equal to the third threshold Th3, the process of the ECU 20 proceeds to step S70.

In step S65, the ECU 20 notifies the user of the electrified vehicle 1 of the degradation of the energy storage cell 45a by displaying, on a display unit of an human-machine interface (HMI) device such as a car navigation system (not shown in FIG. 1), that the degradation has been detected. Alternatively, the ECU 20 notifies a mobile terminal (not shown in FIG. 1) of the user of the electrified vehicle 1 that the degradation of the energy storage cell 45a has been detected, via a communication device (not shown in FIG. 1) included in the ECU 20. The ECU 20 then ends the control for the battery degradation detection.

In step S70, the ECU 20 checks whether the power supply of the electrified vehicle 1 is turned off. When the power source of the electrified vehicle 1 is turned off, the ECU 20 ends the control for the battery degradation detection. When the power supply of the electrified vehicle 1 is not turned off, the process of the ECU 20 proceeds to step S75.

In step S75, the ECU 20 checks whether an interval Δt has elapsed since time ti. The interval Δt is, for example, greater than or equal to 0.01 seconds and less than or equal to 1.0 second. When the interval Δt has elapsed since time ti, the process of the ECU 20 proceeds to step S80. When the interval Δt has not elapsed since time ti, the ECU 20 performs step S75 again. The interval Δt is an example of the “predetermined interval” of the present disclosure.

In step S80, the ECU 20 adds Δt to time ti. The process of the ECU 20 then proceeds to step S85.

In step S85, the ECU 20 increments the cycle count i by one. The ECU 20 then acquires the battery characteristic information Ei again (step S25). As described above, the ECU 20 acquires the battery characteristic information Ei at intervals Δt, and repeats the control cycle for the battery degradation detection (steps S25 to S85) at intervals Δt until the ECU 20 detects degradation (step S60) or confirms that the power supply of the electrified vehicle 1 is turned off (step S70).

In the above embodiment, the ECU 20 determines, for each cycle, degradation based on the degradation index Exi. The degradation index Exi is calculated from Equation (1). That is, when the internal pressure Pbi exceeds the first threshold Th1, or when the cathode potential Vbi exceeds the second threshold Th2, the degradation index Exi increases. This allows the ECU 20 of the electrified vehicle 1 to detect degradation of the energy storage cell 45a at an earlier stage compared to a degradation detection method in which the degradation index Exi is incremented only when the internal pressure Pbi exceeds the first threshold Th1 and the cathode potential Vbi exceeds the second threshold Th2.

The above embodiment illustrates an example in which the ECU 20 calculates the degradation index Exi of the energy storage cell 45a. However, the present disclosure is not limited to this. The ECU 20 may calculate the degradation index Exi of each of two or more of the energy storage cells 45.

### First Modification

The above embodiment illustrates an example in which degradation is detected based on the degradation index Exi. However, the present disclosure is not limited to this. For example, degradation may be detected from an amount of increase in the degradation index Exi.

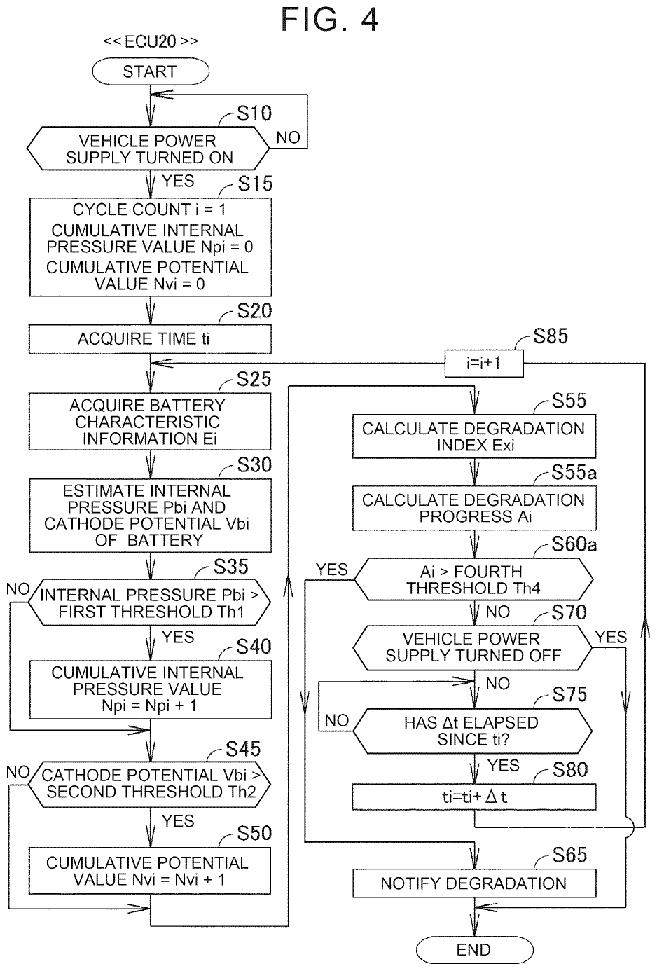

A control flow for battery degradation detection according to a first modification will be described with reference to FIG. 4. Steps S10 to S55 shown in FIG. 4 are the same as those described with reference to FIG. 2. When the ECU 20 records the battery characteristic information Ei in step S25, it records the battery characteristic information Ei in association with a travel distance Di of the electrified vehicle 1. That is, the travel distance Di is the distance traveled by the electrified vehicle 1 at the time the ECU 20 acquires the battery characteristic information Ei.

In step S55a, the ECU 20 calculates a degradation progress Ai. The degradation progress Ai is calculated using Equations (2), (3), and (4).

$$Degradation progress Ai = Δ Εx / Δ D \qquad ( 2 )$$

$$Amount of increase in degradation index Δ Ex = Exi - Exm \qquad ( 3 )$$

$$Amount of increase in travel distance Δ D = Di - Dm \qquad ( 4 )$$

The degradation progress Ai (count value/km) is calculated from the amount of increase in degradation index ΔEx (count value) and the amount of increase in travel distance ΔD (km). The amount of increase in degradation index ΔEx is calculated as the difference between the degradation index Exm at the cycle count m and the degradation index Exi at the cycle count i. The amount of increase in travel distance ΔD is calculated as the difference between the travel distance Dm of the electrified vehicle 1 at the cycle count m and the travel distance Di of the electrified vehicle 1 at the cycle count i. The cycle count m is smaller than the cycle count i. That is, the degradation progress Ai indicates the amount of increase in degradation index per travel distance of the electrified vehicle 1. After the ECU 20 calculates the degradation progress Ai, the process of the ECU 20 proceeds to step S60a.

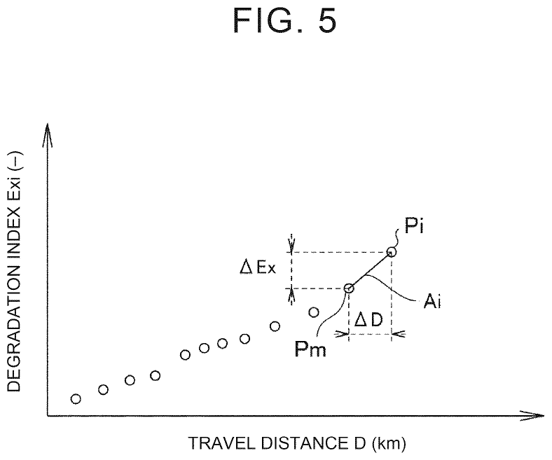

In step S60a, the ECU 20 checks whether the degradation progress Ai is greater than a fourth threshold Th4. The fourth threshold Th4 is, for example, 40. When the degradation progress Ai of the energy storage cell 45a exceeds the fourth threshold Th4, the ECU 20 determines that the energy storage cell 45a has degraded. FIG. 5 is a graph showing the relationship between the degradation index Exi of the energy storage cell 45a and the travel distance D. FIG. 5 shows points Pi, Pm that indicate the degradation index Exi and the travel distance D at the respective cycle counts i, m. The degradation progress Ai is represented by the slope between the points Pi, Pm. When the degradation progress Ai is greater than the fourth threshold Th4, the process of the ECU 20 proceeds to step S65. When the degradation progress Ai is less than or equal to the fourth threshold Th4, the process of the ECU 20 proceeds to step S70.

Steps S65 to S85 shown in FIG. 4 are the same as those shown in FIG. 2.

In the embodiment of the first modification, the ECU 20 determines degradation for each cycle, based on the degradation progress Ai. Accordingly, degradation of the energy storage cells 45 can be detected based on the rate of degradation progression, even when the degradation has not accumulated. That is, the ECU 20 of the electrified vehicle 1 can detect degradation of the energy storage cells 45 at an early stage without waiting for the degradation of the energy storage cells 45 to accumulate.

The embodiments disclosed herein should be considered to be illustrative in all respects and not restrictive. The technical scope of the present disclosure is set forth by the claims rather than by the above description, and is intended to include all modifications within the meaning and scope equivalent to the claims.

What is claimed is:

1. An electrified vehicle comprising:
a battery mounted in the electrified vehicle; and
a control unit, wherein:
the control unit is configured to acquire battery characteristic information of the battery at predetermined intervals, estimate an internal pressure of the battery and a cathode potential of the battery based on the battery characteristic information, increment a cumulative internal pressure value when the internal pressure exceeds a first threshold, and increment a cumulative potential value when the cathode potential exceeds a second threshold; and
the control unit is configured to calculate a degradation index, and when the degradation index exceeds a third threshold, determine that the battery has degraded, the degradation index being the cumulative internal pressure value multiplied by the cumulative potential value.

2. An electrified vehicle comprising:
a battery mounted in the electrified vehicle; and
a control unit, wherein:
the control unit is configured to acquire, at predetermined intervals, battery characteristic information of the battery in association with a travel distance of the electrified vehicle, estimate an internal pressure of the battery and a cathode potential of the battery based on the battery characteristic information, increment a cumulative internal pressure value when the internal pressure exceeds a first threshold, and increment a cumulative potential value when the cathode potential exceeds a second threshold;
the control unit is configured to calculate a degradation index that is the cumulative internal pressure value multiplied by the cumulative potential value; and
the control unit is configured to calculate a degradation progress based on the degradation index, and when the degradation progress exceeds a fourth threshold, determine that the battery has degraded, the degradation progress being an amount of increase in the degradation index per the travel distance.

3. The electrified vehicle according to claim 1, wherein the battery characteristic information includes information on a voltage of the battery, information on a current of the battery, and information on a temperature of the battery.

4. The electrified vehicle according to claim 1, wherein:
the battery is one of energy storage cells that constitute a battery pack;
the internal pressure is a pressure inside a cell case of the energy storage cell; and
the cathode potential is a potential at a cathode terminal of the energy storage cell.

5. The electrified vehicle according to claim 2, wherein the battery characteristic information includes information on a voltage of the battery, information on a current of the battery, and information on a temperature of the battery.

6. The electrified vehicle according to claim 2, wherein:
the battery is one of energy storage cells that constitute a battery pack;
the internal pressure is a pressure inside a cell case of the energy storage cell; and
the cathode potential is a potential at a cathode terminal of the energy storage cell.
